(19) United States
(12) Patent Application Publication
(10) Pub. No.: US 2010/0165251 A1
(43) Pub. Date: Jul. 1, 2010

(54) MICROLENS ASSEMBLY FORMED WITH CURVED INCLINE AND METHOD FOR MANUFACTURING THE SAME, AND LIGHT GUIDING PLATE, BACK LIGHT UNIT AND DISPLAY USING THE SAME

(75) Inventors: Chul Jin Hwang, Gyeonggi-do (KR); Jong Sun kim, Gyeonggi-do (KR); Young Bae Ko, Seoul (KR); Young Moo Heo, Seoul (KR); Jong Deok Kim, Seoul (KR)

Correspondence Address: KED & ASSOCIATES, LLP, P.O. Box 221200, Chantilly, VA, 20153-1200, US

(73) Assignee: KOREA INSTITUTE OF INDUSTRIAL TECHNOLOGY, Cheonan-si Chungeheongnam-do (KR)

(21) Appl. No.: 12/066,551

(22) PCT Filed: Dec. 26, 2007
(86) PCT No.: PCT/KR2007/006844

§ 371 Date: Mar. 12, 2008

(30) Foreign Application Priority Data
Dec. 26, 2006 (KR) 10-2006-0133690
Dec. 26, 2007 (KR) 10-2007-0137481

(51) Int. Cl. G02F 1/13357; G02B 3/08; F21V 8/00; G03F 7/20

(52) U.S. Cl. 349/65; 359/743; 362/615; 362/617; 430/321

(57) ABSTRACT

Provided are a light guiding plate for providing a background light source to a non-emission display device, a back light unit, and a microlens used therein. The microlens having a curved incline formed therein is made of a light transmitting material to reflect and refract light emitted from a light source. Here, the microlens has a polyhedral shape including a bottom face, a top face opposed to the bottom face, and a plurality of side faces formed between the bottom face and the top face, wherein at least one side face crossing a traveling direction of the light emitted from the light source among the plurality of side faces is a curved face inclined about the bottom face.

### TECHNICAL FIELD

The present invention relates to a display device, and more particularly, to a light guiding plate and a back light unit for providing a background light source to a non-emission display device and a microlens assembly used therein.

### BACKGROUND ART

Since a non-emission display device does not have a voluntary light-emitting element, the non-emission display needs to have a back light unit for uniformly transmitting light to the whole screen to be displayed. A liquid crystal display (LCD) device which is a representative non-emission display device includes a particular background light emitting unit for applying light. A back light unit is usually used as the background light emitting unit.

The back light unit (BLU) is a light source device supplying light from the rear surface of the liquid crystal display device. The back light unit includes a light source, a reflecting plate, a light guiding plate, and diffusing plate.

The light guiding plate (LGP) serves to uniformly radiate light emitted from the light source located on one side or both sides to the entire surface of the liquid crystal display device located above. In the conventional light guiding plate, the diffusion of light was guided by forming V-shaped grooves or arranging diffusing ink dots with a constant size on a substrate. The V-shaped grooves or the diffusing ink dots are optical patterns for guiding the diffusing of light by reflecting or refracting the light from the light source and is also called a microlens.

The V-shaped grooves are formed by mechanically processing a substrate, but since the size of the grooves is very small in the unit of the formation thereof is not easy and requires much cost. The diffusing ink dots have a problem that thermal efficiency is very low due to absorption and scattering of the diffusing ink.

FIG. 1 is a sectional view schematically illustrating a structure of a conventional liquid crystal display device. A light guiding plate 10 is located at the bottom of a back light unit and serves to transmit light emitted from a light source 15 to a liquid crystal panel 13. For the purpose of the display device, the light source is disposed on a side surface of the light guiding plate 10 and the liquid crystal panel 13 is disposed above the light guiding plate. Accordingly, the light guiding plate 10 should refract or reflect the light laterally incident from the light source 15 upward. For the purpose of this, optical patterns 17 called micro lenses are formed in the light guiding plate 10. When an angle of the light about the horizontal plane of the light guiding plate is an output angle θ, the light guiding plate using the micro lenses such as the V-shaped grooves or the ink dots has a low output angle θ of 20° to 40°. Since the brightness of the liquid crystal display device is lowered due to the low output angle and thus an image to be viewed may vary depending on the angle, the refraction and diffusion of light should be induced by interposing a prism film 12 or a diffusing film 11 between the light guiding plate 10 and the liquid crystal panel 13, independently of the light guiding plate.

The output angle of the liquid crystal panel 13 can be enhanced close to 90° by the use of the prism film 12 or the diffusing film 11. However, the addition of the prism film or the diffusing film enhances the total thickness and weight of the liquid crystal display device, which is against the technical tendency of a decreases in thickness and weight, increases the cost for manufacturing a display device, and complicates the manufacturing process.

Therefore, there is a need for a back light unit and a display device which can enhance the intensity of light without using a prism film or a diffusing film.

### DISCLOSURE OF THE INVENTION

### Technical Goal

The invention is contrived to solve the above-mentioned problems. A goal of the invention is to provide a microlens assembly that can transmit light from a light source to a display screen with high brightness and uniformity, a method of manufacturing the microlens assembly, a light guiding plate, a back light unit, and a display device employing the microlens assembly.

### Technical Solution

In order to accomplish the above-mentioned goal, according to an aspect of the invention, there is provided a microlens made of a light transmitting material to reflect and refract light emitted from a light source, wherein the microlens has a polyhedral shape including a bottom face, a top face opposed to the bottom face, and a plurality of side faces formed between the bottom face and the top face and at least one side face crossing a traveling direction of the light emitted from the light source among the plurality of side faces is a curved face inclined about the bottom face. Here, it is preferable that the curved face is formed so as to reduce the volume of the polyhedral shape. It is preferable that the angle of the curved face inclined about the bottom face is in the range of 20° to 50°.

According to another aspect of the invention, there is provided a method of manufacturing a microlens, including: a photosensitive material applying step of applying a photosensitive material to a surface of a substrate; a first exposure step of applying light to the surface of the substrate through a mask on which a polygonal pattern of which at least one side is replaced with a curve is formed; a second exposure step of applying light to the surface of the substrate through the mask at an angle different from that of the first exposure step; and a developing step of developing the photosensitive material exposed in the first exposure step and the second exposure step.

The method may further include an imprinting step of performing an imprinting operation using the developed substrate as a stamp. The method may further include a metal layer forming step of forming a metal layer on the developed substrate before the imprinting step.

On the other hand, the method may further include: a metal layer forming step of forming a metal layer on the developed substrate; a metal layer separating step of separating the metal layer from the substrate; and an imprinting step of performing an imprinting operation using the separated metal layer as a stamp.

It is preferable that the method further includes a relative moving step of allowing the substrate to move relative to the mask between the first exposure step and the second exposure step.

In the method, it is preferable that the first exposure step is to apply light through a mask on which a quadrangular pattern of which one side is replaced with a curve is formed. In this case, it is preferable that the mask is one of a film mask and a chromium mask.

According to another aspect of the invention, there is provided a method of manufacturing a microlens having a curved incline formed therein, the method including: a step of applying a photosensitive material to a surface of a substrate; a first exposure step of applying light to the surface of the substrate through a first mask having a polygonal pattern; a second exposure step of applying light to the surface of the substrate through a second mask having a pattern, which has a polygonal shape of which at least one side is replaced with a curve and which has an area equal to or less than that of the pattern of the first mask, at an angle different from that in the first exposure step; and a developing step of developing the exposed photosensitive material exposed in the first exposure step and the second exposure step.

A method of manufacturing a microlens having a curved incline according to still another aspect of the invention includes: a photosensitive material applying step of applying a photosensitive material to a mask substrate having a polygonal pattern, at least one side of which is replaced with a curve, formed thereon; a first exposure step of applying light to the surface of the mask substrate; a second exposure step of applying light to the surface of the mask substrate at an angle different from that in the first exposure step; and a developing step of developing the photosensitive material exposed in the first exposure step and the second exposure step.

A light guiding plate employing a microlens having a curved incline according to still another aspect of the invention includes: a substrate that is made of a light transmitting material to transmit light emitted from a light source; and a microlens that is formed to protrude from the surface of the substrate, that is made of a light transmitting material to reflect and refract the light emitted from the light source, and that has a polyhedral shape including a bottom face coming in contact with the surface of the substrate, a top face opposed to the bottom face, and a plurality of side faces formed between the bottom face and the top face, wherein at least one side face crossing the traveling direction of the light emitted from the light source among the plurality of side faces is a curved face inclined about the bottom face. Here, it is preferable that the curved face of the microlens is formed so as to reduce the volume of the microlens.

A light guiding plate employing a microlens having a curved incline according to still another aspect of the invention includes a substrate that is made of a light transmitting material to transmit light emitted from a light source and that has a micro groove of a polyhedral shape having a bottom face and a plurality of side faces, wherein at least one face crossing the traveling direction of the light emitted from the light source among the plurality of side faces of the micro groove is a curved face inclined about the bottom face. Here, it is preferable that the curved face of the micro groove is formed so as to enhance the volume of the substrate.

A back light unit employing a microlens having a curved incline according to still another aspect of the invention includes: a light source; a light guiding plate including a substrate that is made of a light transmitting material to transmit light emitted from a light source and a microlens that is formed to protrude from the surface of the substrate, that is made of a light transmitting material to reflect and refract the light emitted from the light source, and that has a polyhedral shape including a bottom face coming in contact with the surface of the substrate, a top face opposed to the bottom face, and a plurality of side faces formed between the bottom face and the top face, wherein at least one side face crossing the traveling direction of the light emitted from the light source among the plurality of side faces is a curved face inclined about the bottom face; and a reflecting plate that is disposed on one surface of the light guiding plate and that reflects the light emitted from the light source.

A back light unit employing a microlens having a curved incline according to still another aspect of the invention includes: a light source; a light guiding plate including a substrate that is made of a light transmitting material to transmit light emitted from a light source and that has a micro groove of a polyhedral shape having a bottom face and a plurality of side faces, wherein at least one face crossing the traveling direction of the light emitted from the light source among the plurality of side faces of the micro groove is a curved face inclined about the bottom face; and a reflecting plate that is disposed on one surface of the light guiding plate and that reflects the light emitted from the light source.

A display device employing a microlens having a curved incline according to still another aspect of the invention includes: a light source; a light guiding plate including a substrate that is made of a light transmitting material to transmit light emitted from a light source and a microlens that is formed to protrude from the surface of the substrate, that is made of a light transmitting material to reflect and refract the light emitted from the light source, and that has a polyhedral shape including a bottom face coming in contact with the surface of the substrate, a top face opposed to the bottom face, and a plurality of side faces formed between the bottom face and the top face, wherein at least one side face crossing the traveling direction of the light emitted from the light source among the plurality of side faces is a curved face inclined about the bottom face; a reflecting plate that is disposed on one surface of the light guiding plate so as to reflect the light; and a variable mask that is disposed on the other surface of the light guiding plate and that displays an image by blocking or transmitting the light reflected and refracted by the light guiding plate.

A display device employing a microlens having a curved incline according to still another aspect of the invention includes a light source; a light guiding plate including a plate-like base layer that is made of a light transmitting material to transmit light emitted from a light source and a micro groove that includes a reflecting/refracting layer formed monolithically on the base layer and made of a light transmitting material to reflect and refract the light emitted from the light source, wherein the reflecting/refracting layer is a polyhedral groove including a bottom face opposed to the surface of the base layer and a plurality of side faces and at least one side face crossing the traveling direction of the light emitted from the light source among the plurality of side faces is a curved face inclined about the bottom face; a reflecting plate that is disposed on one surface of the light guiding plate so as to reflect light; and a variable mask that is disposed on the other surface of the light guiding plate and that displays an image by blocking or transmitting the light reflected and refracted by the light guiding plate.

In the display device, it is preferable that the variable mask includes: a first substrate on which electrodes assigned to pixels are arranged; a second substrate that is bonded to the first substrate and on which an electrode common to the pixels; and a liquid crystal layer interposed between the first substrate and the second substrate.

### ADVANTAGES

In the above-mentioned microlens assembly with a curved incline formed therein according to the invention, since the light from the side surface can be transmitted vertically, it is possible to enhance the brightness of a non-emission display device by applying the microlens assembly to a light guiding plate or a back light unit of the non-emission display device. Particularly, since the radius of curvature of the curved incline can be adjusted to uniformly transmit the light, it is possible to enhance the uniformity of brightness of the display device. The enhancement in brightness and the enhancement in uniformity of brightness can be adjusted by changing the arrangement of micro lenses and the number of micro lenses.

### BRIEF DESCRIPTION OF THE DRAWINGS

FIG. 1 is a sectional view schematically illustrating a structure of a known liquid crystal display device.

FIG. 2 is a perspective view of a microlens having a curved incline formed therein according to an embodiment of the invention.

FIG. 3 is a diagram schematically illustrating reflection and refraction paths of light in use of the exemplary embodiment shown in FIG. 2.

FIG. 4 is a perspective view illustrating a microlens having a curved incline formed therein according to another embodiment of the invention.

FIG. 5 is a sectional view illustrating a state in use of a light guiding plate employing a microlens assembly having curved inclines formed therein according to an embodiment of the invention.

FIG. 6 is a partial perspective view illustrating a light guiding plate employing a microlens assembly having curved inclines formed therein according to another embodiment of the invention.

FIG. 7 is an exploded perspective view illustrating a display device employing a microlens assembly having curved inclines formed therein according to an embodiment of the invention.

FIG. 8 is a diagram schematically illustrating a conventional method of measuring a viewing angle.

FIG. 9 is a diagram visualizing the measurement result of a viewing angle using a conventional semi-spherical microlens.

FIG. 10 is a diagram visualizing the measurement result of the viewing angle using another conventional microlens.

FIG. 11 is a perspective view illustrating the conventional microlens used in measuring the viewing angle in FIG. 10.

FIG. 12 is a diagram visualizing the measurement result of a viewing angle of the light guiding plate employing the microlens having a curved incline formed therein according to an embodiment of the invention.

FIG. 13 is a diagram visualizing the measurement result of a viewing angle when the microlens having a curved incline is formed in the front and rear surfaces of the light guiding plate according to an embodiment of the invention.

FIG. 14 is a diagram visualizing the measurement result of the viewing angle with a variation in inclination angle of the curved incline of the microlens about a bottom face in the light guiding plate employing the microlens having a curved incline according to an embodiment of the invention.

FIG. 15 is a flowchart illustrating a method of manufacturing a microlens having a curved incline formed therein according to an embodiment of the invention.

FIG. 16 is a perspective view illustrating a mask used in the embodiment shown in FIG. 15.

FIG. 17 is a diagram illustrating a first exposure step of the embodiment shown in FIG. 15.

FIG. 18 is a diagram illustrating a second exposure step of the embodiment shown in FIG. 15.

FIG. 19 is a flowchart illustrating a method of manufacturing a microlens having a curved incline formed therein according to another embodiment of the invention.

FIG. 20 is a diagram illustrating a first exposure step of the embodiment shown in FIG. 19.

FIG. 21 is a diagram illustrating a second exposure step of the embodiment shown in FIG. 19.

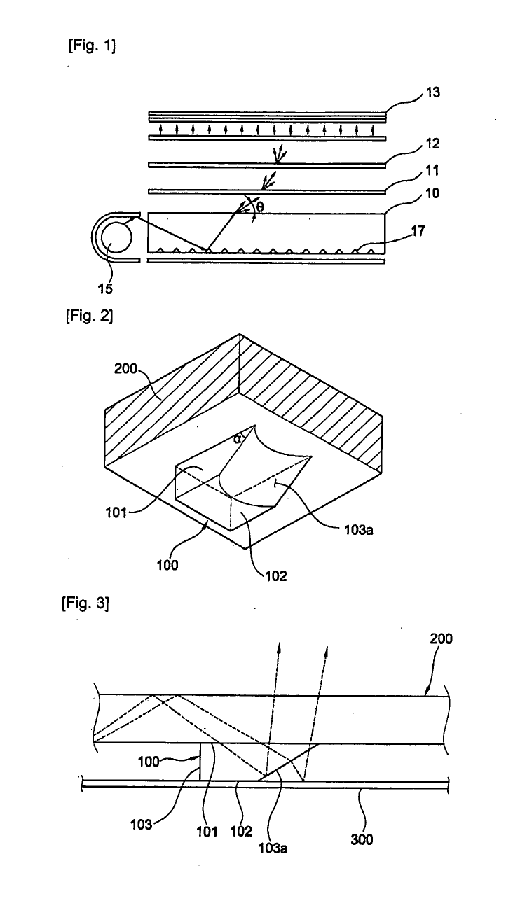

### DESCRIPTION OF EXEMPLARY EMBODIMENTS

Hereinafter, exemplary embodiments of the invention will be described in detail with reference to the accompanying drawings. In the below description, names of elements are defined in consideration of functions thereof, are not intended to limit the technical elements of the invention, and can be called other names in the art. Reference numerals denotes the elements for the purpose of convenient explanation and the details of the drawings denoted by the reference numerals are not intended to limit the elements to the scope in the drawings. Any modified example having functional similarity and identity may be considered as an equivalent example and any modified example having some modified elements but having functional similarity and identity may be employed as an equivalent example.

Hereinafter, a microlens having a curved incline according to an exemplary embodiment of the invention will be described in detail with reference to the accompanying drawings.

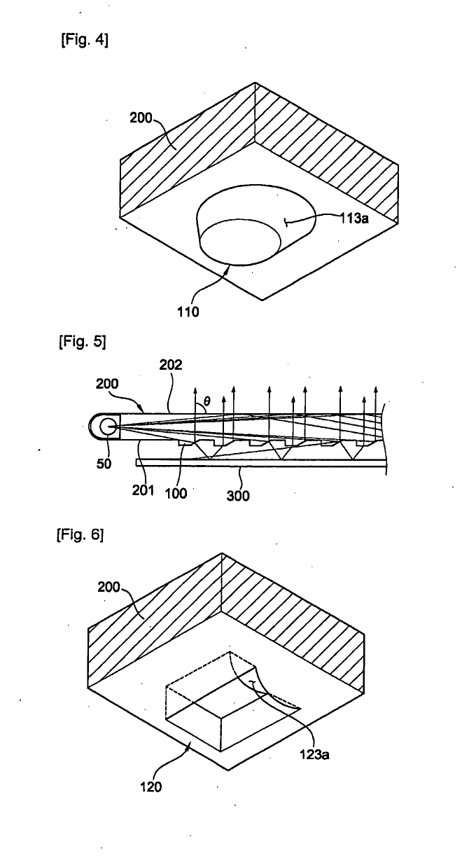

FIG. 2 is a perspective view illustrating a microlens having a curved incline according to an exemplary embodiment of the invention. FIG. 3 is a diagram schematically illustrating reflection and refraction paths of light in use of the embodiment shown in FIG. 2. FIG. 4 is a perspective view illustrating a microlens having a curved incline according to another embodiment of the invention.

A microlens 100 is made of a light transmitting material so as to reflect and refract light. Since the microlens 100 is made of a completely transparent material but the completely transparent material is different from that of the outside, the interface therebetween simultaneously reflects and refract light.

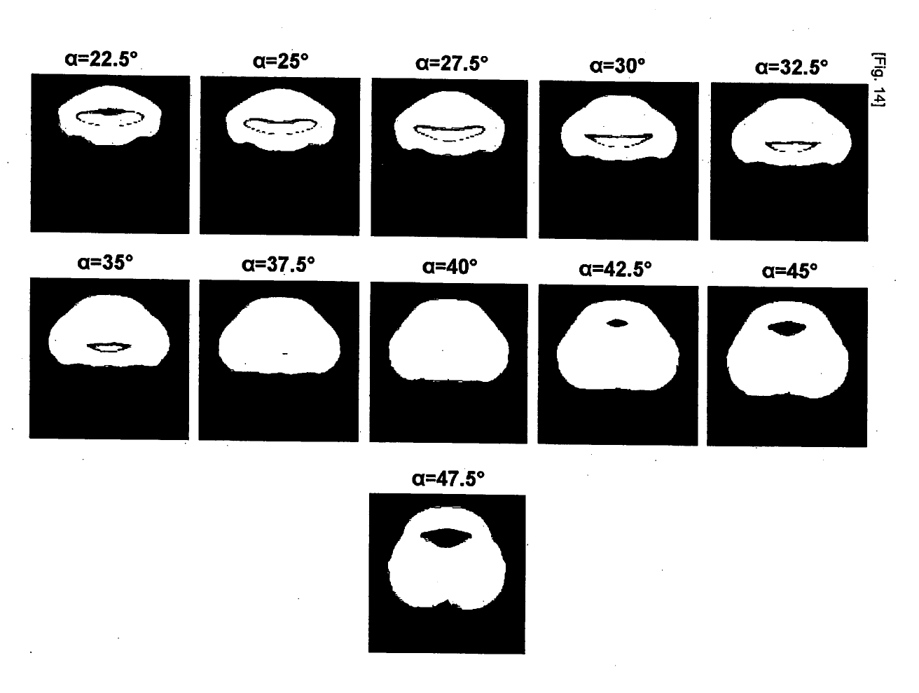

The microlens 100 has a polyhedral shape and at least one face thereof is a curved face. The microlens 100 shown in FIG. 2 has a bottom face 101 contacting with a substrate 200, a top face 102 opposed to the bottom face 101, and plural side faces 103 formed between the bottom face 101 and the top face 102 and thus has a polyhedral shape, that is, a shape of a truncated pyramid. The shape of the microlens 100 is not limited to the above-mentioned shape, but may be various polyhedral shapes such as a prism, a cylinder, a pyramid, a cone, and combinations thereof. However, one side face 103a of the plural side faces 103 is a curved face and the curved face should be formed to be inclined by a predetermined inclination angle α about the bottom face 101. An advantage of the inclination angle α of the curved face about the bottom face 101 will be described later with reference to FIG. 14. In the below description, the curved incline means a curved face inclined about the bottom face 101. The side face 103 as the curved incline is disposed to cross the traveling direction of light emitted from a light source in use of the microlens 101.

The specific shape of the curved incline can be modified in various forms such as a cylindrical face, a conical face, and a spherical face. In addition, the curved incline can be modified in a convex curved face or a concave curved face. The curved incline of the microlens shown in FIG. 2 is has a shape close to a cylindrical face, but the curved incline 113a of the microlens 110 shown in FIG. 4 has a conical shape and thus the whole side face thereof is a conical face. The curve incline 103a of the microlens shown in FIG. 2 is a curved face formed to reduce the volume of the microlens 100, that is, a concave curved face, but the curved incline 113a of the microlens 110 shown in FIG. 4 is a curved face formed to enhance the volume of the microlens, that is, a convex curved face.

On the other hand, it is preferable that the microlens is made of a material capable of holding a finite shape such as synthetic resin, but an infinite fluid such as air may be enclosed in a frame having a microlens shape so as for the frame to perform the function of the microlens. This example will be described in detail again along with a light guiding plate.

FIG. 3 shows reflection and refraction paths of the microlens 100 in use by the use of dotted arrows. Here, a reflecting plate 300 reflecting light is disposed below the microlens 100 and a liquid crystal panel not shown is disposed above the microlens. A light source not shown is disposed at one end of the substrate 200. When the light source emits light, the light refracted and reflected while passing through the substrate 200 reaches the side face 103a as the curved incline of the microlens 100. A part of the light is reflected by the side face 103a and then travels to the upside of the microlens 100, that is, toward the liquid crystal panel. The other of the light is refracted while passing through the side face 103a, reflected by the reflecting plate 300, and then travels toward the liquid crystal panel finally. It is illustrated in FIG. 3 that the dotted arrow goes up vertically with respect to the paper surface after passing through the microlens 100, which means that an output angle of the light is made to be substantially vertical by the microlens 100.

The substrate 200 is a plate-like member for supporting the microlens 100 and is made of a light transmitting material. The plural microlenses 100 may be formed monolithically with the substrate 200, or the plural microlenses 100 may be independently formed and than may be arranged and attached onto one surface of the substrate 200. It is shown in FIGS. 2 and 3 for the purpose of explanation that the microlens 100 is formed on the substrate 200, but when the substrate 200 having the microlens 100 formed therein is a plate shape, the substrate serves as the light guiding plate employing the microlens according to the invention.

FIG. 5 is a sectional view illustrating a state in use of a light guiding plate employing the microlens assembly having curved inclines according to an embodiment of the invention.

Plural microlenses 100 protrude from the bottom surface of the light guiding plate, that is, the substrate 200 and the reflecting plate 300 is disposed below the microlenses in the drawing. Here, the respective microlenses 100 are equal to the microlens having the curved incline described above. Although not shown, a liquid crystal panel is disposed above the light guiding plate. On the other hand, a light source 50 is disposed on one side of the light guiding plate. Accordingly, the light emitted from the light source travels laterally in average along the light guiding plate. The light traveling along the light guiding plate, that is, the substrate 200, reaches the side face as the curved incline of the microlens 100 through refraction and reflection. The light reflected by the curved incline travels just upward. The light traveling downward by refraction is reflected again by the reflecting plate 300 and travels upward. As a result, the light reflected by the curved incline and the refracted light both travel upward. At this time, the output angle θ is close to 90° without using a prism film or a diffusing film.

FIG. 6 is a partial perspective view illustrating a light guiding plate employing a microlens assembly having curved inclines according to another embodiment of the invention.

Only a part of a light guiding plate, that is, the substrate 200, including one micro groove 120 is shown in FIG. 6, but plural micro grooves 120 are formed on the bottom face of the light guiding plate, that is, the substrate 200. The micro groove 120 has the same shape as the microlens having the curved incline described above. That is, the light guiding plate according to this embodiment is an example where a groove having the same shape as the microlens 100 shown in FIG. 2 is formed. Here, the curved incline 123a is formed to enhance the volume of the substrate 200. The above-mentioned microlens having the curved incline is protruded, but the microlens according to this embodiment is depressed. In this embodiment, the material of the microlens is an example of an infinite shaped fluid such as air.

On the other hand, a back light unit according to the invention is formed by disposing the light source on one side of the light guiding plate and adding the reflecting plate below the light guiding plate. The back light unit allows the light emitted from the light source to travel in one direction by reflection and refraction, thereby providing a surface light source of which the entire surface emits light.

On/Off signals can be displayed by masking the surface light source provided by the back light unit. In addition, by dividing the light-emitting surface of the back light unit provided from the back light unit, defining the divided regions as pixels, ad masking the pixels to be turned on and off, a sign or an image can be displayed or a moving image can be also displayed. By disposing color filters of different colors in the pixels, a color image can be displayed. The device for variably masking the light-emitting surface of the back light unit can be referred to as a variable mask. Accordingly, by disposing the variable mask in the back light unit, it is possible to embody the display device according to the invention. A representative example of the variable mask includes a liquid crystal panel. The liquid crystal panel includes a first substrate having electrodes for controlling the pixels, a second substrate having an electrode common to all the pixels, and a liquid crystal layer interposed between the substrates and further includes polarizing plates disposed on both surfaces of the first substrate and second substrate bonded to each other. For example, as the variable mask, a TFT liquid crystal panel including a substrate having TFT (Thin Film Transistors) formed thereon, a substrate having color filters formed thereon, a liquid crystal layer interposed therebetween, and polarizing plates disposed on both surfaces of the TFT substrate and the color filters bonded to each other can be used.

The display device according to the invention described above will be described in detail below.

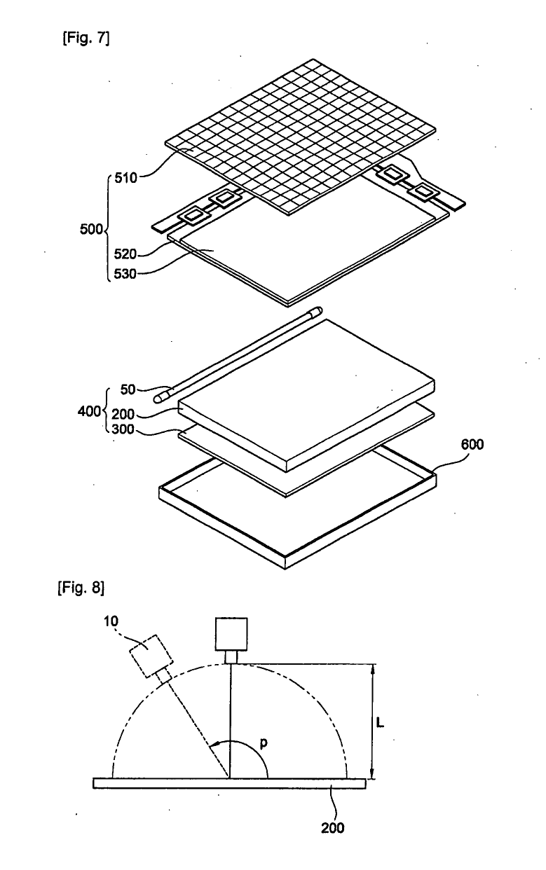

FIG. 7 is an exploded perspective view illustrating a display device employing the microlens having a curved incline according to an embodiment of the invention. The display device includes a back light unit 400, a liquid crystal panel 500, and a mold frame 600.

The liquid crystal panel 500 displays images such as characters, numerals, and figures by blocking or transmitting the light emitted from the back light unit 400. For example, the liquid crystal panel 500 can display colors of the pixels on the screen by adjusting the transmittance of light passing through the liquid crystal layer 530 depending on the magnitude of the applied voltage.

The liquid crystal panel 500 includes a color filter substrate 510, a liquid crystal substrate 520, and a liquid crystal layer 530.

The color filter substrate 510 is disposed opposite the liquid crystal substrate 520 and includes a color filter for displaying the colors of the pixels. The color filter is a filter displaying predetermined colors such as red, green, and blue. A common electrode made of a transparent conductive material such as ITO (Indium Tin Oxide) or IZO (Indium Zinc Oxide) is formed in the color filter substrate.

The liquid crystal substrate 520 serves to control the directionality of liquid crystal molecules. The liquid crystal substrate 520 includes plural gate lines, plural data lines, plural switching elements, and plural pixel electrodes. The plural pixels can be defined in a matrix in which the gate lines and the data lines intersect each other.

The liquid crystal layer 530 is located between the color filter substrate and the liquid crystal substrate. Liquid crystal means a material in which the alignment of molecules is irregular in a direction and regular in another direction, thereby optically displaying a crystal state. Accordingly, the transmittance of light can be adjusted depending on the alignment of the liquid crystal molecules and the alignment of the liquid crystal molecules can be changed with an application of a voltage or an external force.

The back light unit 400 serves to apply light to the liquid crystal panel 500. The back light unit 400 includes a light source 50, a reflecting plate 300, and a light guiding plate 200 having the microlenses. The light guiding plate 200 reflects or refracts the light emitted from the light source 50 toward the front surface where the liquid crystal panel 500 is disposed.

By forming the plural microlenses 100 and 110 (see FIGS. 2 and 4) or the plural micro grooves 120 (see FIG. 6) in the light guiding plate 200, it is possible to enhance the intensity of light emitted from the light source. In addition, by randomly or uniformly distributing several hundreds, thousands, or ten thousands microlenses or micro grooves in the light guiding plate 200, it is possible to uniformize the brightness of light traveling toward the front side of the light guiding plate 200.

Therefore, by enhancing the intensity of light emitted from the back light unit 400 including the microlenses, it is possible to make it unnecessary to use a prism film or a diffusing film.

The mold frame 600 serves as a structural support for keeping the back light unit 400 and the liquid crystal panel 500 in parallel with a constant gap. The mold frame 600 can be formed by an injection molding method of injecting melted resin into a mold and cooling the resin.

A back light unit according to an exemplary embodiment of the invention is described now with reference to FIG. 5.

As shown in FIG. 5, the back light unit 400 includes the light source 50, the reflecting plate 300, and the light guiding plate 200.

The light source 50 is a source for applying light on to a display screen from a linear light source such as CCFL (Cold Cathode Fluorescence Lamp).

The reflecting plate 300 serves to reflect the light having passed the rear surface to the light guiding plate 200 back, when a part of light does not pass through the front surface of the light guiding plate but passes through the rear surface of the light guiding plate 200.

The reflecting plate 300 is formed by coating a base material having the same size of the light guiding plate 200 with a high-reflectivity material. The base material such as stainless steel (SUS), brass, aluminum, and PET can be coated with silver (Ag). In order to prevent the color of the reflecting plate 300 from being changed due to the heat from the light source 50, the reflecting plate 300 can be coated with titanium or a polymer having high reflectivity.

The light guiding plate 200 allows the light emitted from the light source 50 to travel toward the front surface of the display screen. The light guiding plate 200 uniformly diffuses the linear light or a dot light from the light source 50 to one surface to form the surface light.

Accordingly, the light guiding plate 200 is made of a material having high transmittance of light, such as PMMA, and can be made of olefin-based transparent plastic (COC) having small specific gravity for a decrease in weight.

The light guiding plate 200 can be classified into a flat panel type and a wedge type depending on the shape thereof and can be classified into a printed type and a non-printed type depending on the emission type.

In the flat panel type, the light guiding plate 200 is shaped in a flat structure by an extruding, injecting, or casting method and the light source 50 is located on both edges of the light guiding plate 200, whereby the light is input from both sides. In the wedge type, the light is input from the light source located on one side. Since the wedge type is excellent in light efficiency and is easily reduced in thickness, it is mainly used for a small display.

In the back light unit according to the invention, the light guiding plate 200 is a non-printed light guiding plate in which plural microlenses having a curved incline according to the invention are formed. The microlenses may be disposed on the rear surface 201 or the front surface 202 of the light guiding plate 200, or may be formed on both sides.

Operations of a back light unit according to an embodiment of the invention will be described now.

The light from the light source 50 is obliquely applied to the light guiding plate. When the light passes through the rear surface 201 of the light guiding plate 200, the light is reflected toward the light guiding plate again by the reflecting plate. The optical path of the light can be changed by the microlens 100 formed in the light guiding plate 200.

When the microlenses 100 having a curved incline are protruded or depressed in the light guiding plate 200, light is refracted or reflected depending to the shape of the microlenses. When one face of the microlens 100 is the curved incline, the obliquely input light can be totally reflected, partially reflected, or refracted by the curved incline.

The light can change its traveling direction and travel toward the front surface 202 of the light guiding plate 200 by means of the reflection or refraction.

In the back light unit according to the invention, the output angle can be increased by the microlens 100 having the curved incline, thereby enhancing the brightness of the display device employing the back light unit according to the invention.

The output angle is adjusted to be great every position of the light guiding plate 200 by the several hundreds, thousands, or ten thousands microlenses 100 randomly or uniformly distributed in the light guiding plate 200, thereby uniformizing the brightness of the display screen.

Optical performance of the microlens having a curved incline and the light guiding plate employing the microlens according to the invention will be described now.

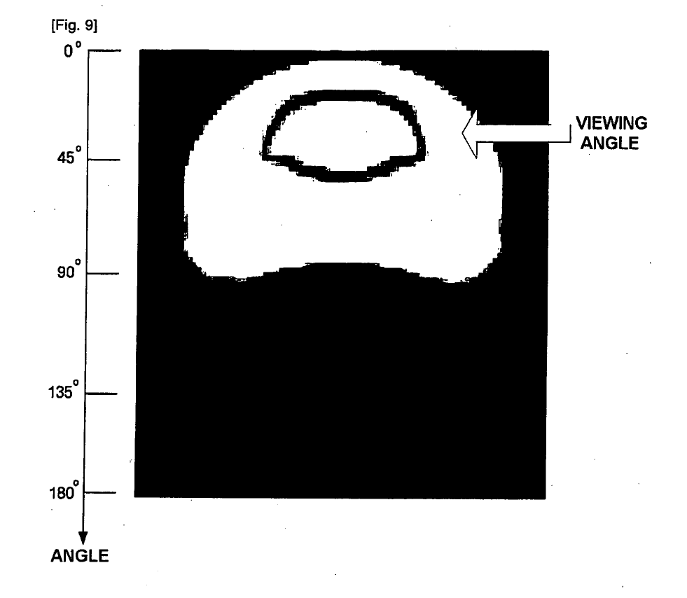

FIG. 8 is a diagram schematically illustrating a conventional method of measuring a viewing angle.

As shown in FIG. 8, in order to measure the viewing angle ρ, the intensity of light is measured while moving a luminance meter 10 on a semi-sphere above the light guiding plate 200.

An angle of the luminance meter at a position where the measured intensity of light is the largest is defined as the viewing angle ρ. The viewing angle ρ varies depending on the output angle which is an angle of the light output from the light guiding plate 200. Accordingly, the viewing angle ρ at which the measured intensity of light is the largest is matched with the output angle of the light output from the light guiding plate 200.

Therefore, by measuring the viewing angle ρ, it is possible to measure the output angle of the light guiding plate 200 having various types of microlenses.

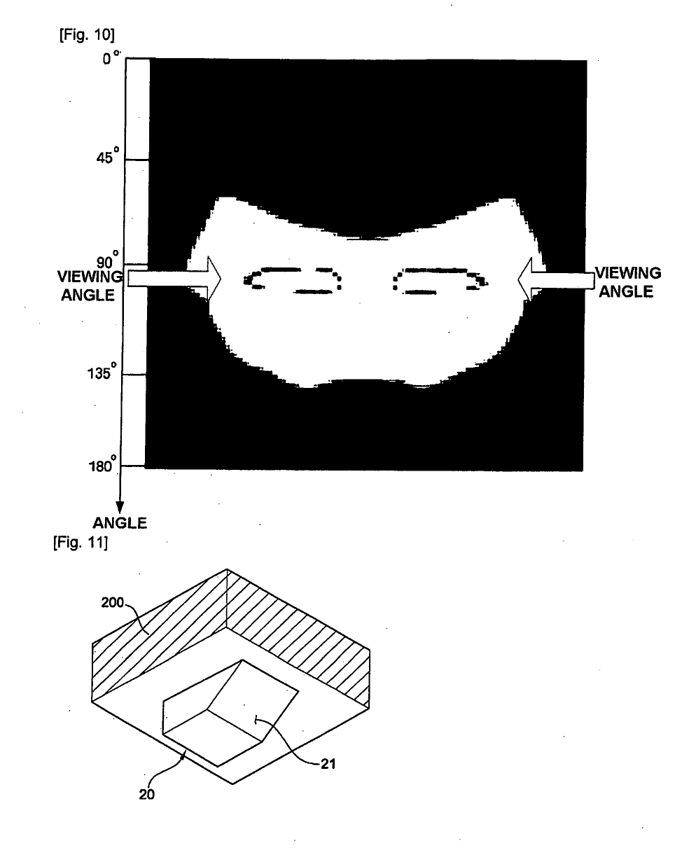

The commercial luminance meter outputs the measured values as images and usually outputs color images. That is, a viewing angle at which the intensity of light is small is expressed by blue, a viewing angle at which the intensity of light is large is expressed by red, and a viewing angle at which the intensity of light is the largest is expressed by white. FIGS. 9 and 10 originally show the color images, but the portion having the largest intensity of light can be recognized even in white and black images thereof. Since a portion expressed by white in the color images is surrounded with a portion expressed by red and a part of the portion expressed by red is replaced with a dark portion in the white and black images, the portion having the largest intensity of light in the white and black image corresponds to the portion inside the closed loop at the center of the images.

The measurement results of the viewing angle ρ using various microlenses are described with reference to FIGS. 9, 10, 12, 13, and 14. FIGS. 9, 10, 12, and 13 show the measurement results of the viewing angle when the same diffusing film is disposed on the microlenses for the purpose of clear comparison and FIG. 14 shows the measurement result of the viewing angle using the diffusing film.

FIG. 9 is a diagram visualizing the measurement result of a viewing angle using a conventional semi-spherical microlens.

In FIG. 9, a portion surrounded with a closed loop and indicated by an arrow is a region at which the intensity of light is the largest. This region corresponds to the viewing angle of about 30°. That is, the conventional semi-spherical microlens has a viewing angle or an output angle of about 30°. This is because it is difficult to change the optical path of light toward the front surface of the light guiding plate by means of the reflection or refraction of light by the use of the semi-spherical curved face.

Accordingly, even when plural semi-spherical microlenses are formed in the light guiding plate 200, the viewing angle is about 30° using the microlenses and thus the intensity of light is not enough. In addition, since the angle of light output therefrom is about 30° about the front surface of the light guiding plate 200, which is small, light beams output from the microlenses reinforce or cancel each other, thereby making the brightness of light on the front surface of the light guiding plate 200 non-uniform.

FIG. 10 is a diagram visualizing the measurement result of the viewing angle of the light guiding plate using another conventional microlens. The microlens 20 has an incline 21 on one face as shown in FIG. 11, but the incline 21 is of a plane type.

A region at which the intensity of light is the largest in FIG. 10 is regions inside two closed loops indicated by arrows, where the viewing angle is approximately 90°. However, the region having a high output angle is divided into two regions and thus the light is not concentrated on one region. This means that the intensity of light can be enhanced, but the light is not uniformly distributed.

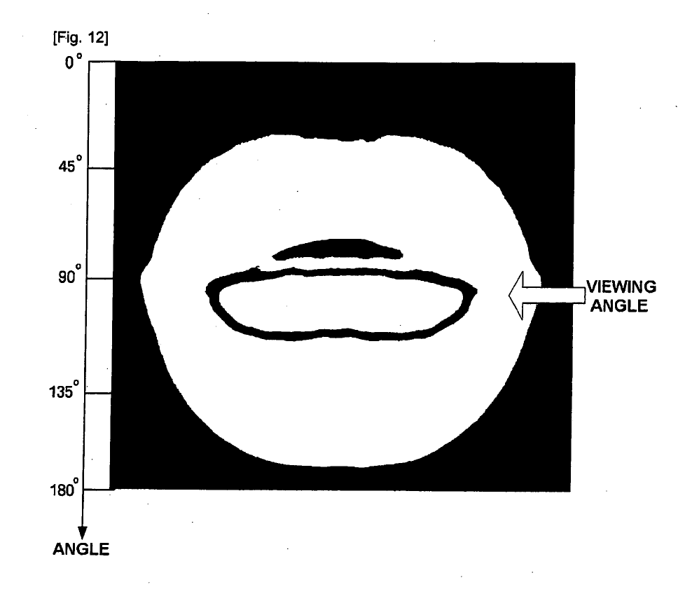

FIG. 12 is a diagram visualizing the measurement result of the viewing angle of the light guiding plate employing the microlens having a curved incline according to the invention. The shape of the microlens having a curved incline is as shown in FIG. 2 and the microlenses are formed on the rear surface of the light guiding plate, that is, the substrate 200.

A region at which the intensity of light is the largest in FIG. 12 is a region inside the closed loop indicated by an arrow, where the viewing angle thereof is about 90°. Accordingly, it can be seen that the viewing angle or output angle can be enhanced to about 90° by the use of the curved incline of the microlens.

Only a single closed loop is shown in FIG. 12, which means that the light is concentrated on one region, while two closed loops are shown in FIG. 10. The area is also greater than the total area of the two closed loops shown in FIG. 10. As a result, it can be seen that the intensity and uniformity are both improved. This is because the curved incline serves to collect the light. Accordingly, it is possible to adjust the degree of concentration or diffusion of light by changing the curvature and shape of the curved incline.

Several hundreds, several thousands, or several ten thousands microlens 100 having a curved incline can be distributed on the light guiding plate 200. Accordingly, since the output angle of the light reflected or refracted by the microlenses having a curved incline is close to 90°, the intensity of light emitted from a single microlens to the front surface of the light guiding plate 200 is increased.

Therefore, a user can see an image having relatively high brightness and can relatively easily adjust the brightness and uniformity of an image to be displayed by the use of the distribution of the microlenses having a curved incline.

Since the output angle increases to about 90°, it is not necessary to use a prism film or diffusing film for enhancing the output angle, thereby reducing the manufacturing cost.

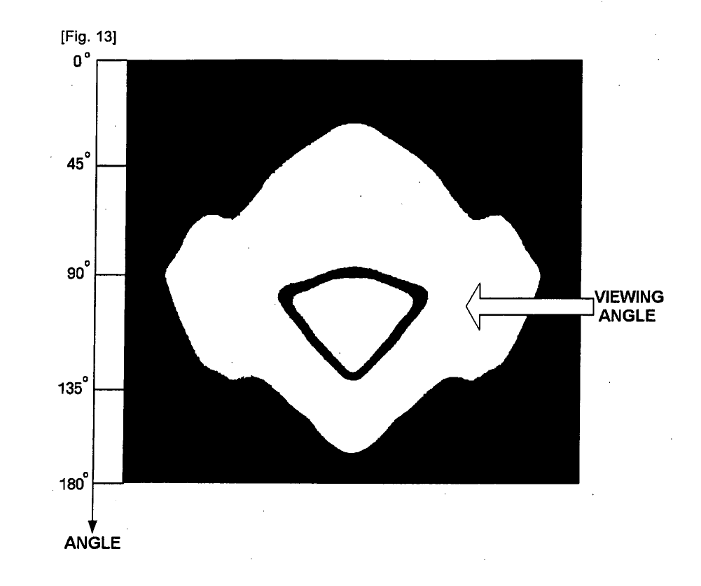

FIG. 13 is a diagram visualizing the measurement result of a viewing angle when the microlens having a curved incline is formed in the front and rear surfaces of the light guiding plate according to an embodiment of the invention.

FIG. 13 shows the result of the viewing angle measured when the microlens 100 having the curved incline according to the invention is formed both on the front surface 202 and the rear surface 201 of the light guiding plate, that is, the substrate 200. A region at which the intensity of light is the largest is a region inside the closed loop similar to a diamond shape.

The result of the viewing angle measured when the microlens 100 having the curved incline is formed on the rear surface 201 of the light guiding plate 200 is shown in FIG. 12. In comparison with the result shown in FIG. 12, it can be seen that the degree of light concentration is higher when the microlens is formed both on the rear surface and the front surface of the substrate 200.

FIG. 14 is a diagram visualizing the measurement result of the viewing angle with a variation in inclination angle α (see FIG. 2) of the curved incline of the microlens about the bottom face in the light guiding plate employing the microlens having a curved incline according to the invention.

The viewing angle was measured while increasing the inclination angle α from 22.5° to 47.5° by 2.5°. When the inclination angle is relatively small, a clear closed loop appears at the upper center of the white and black image and thus the intensity of light, that is, the brightness, is relatively high. As the inclination angle increases, the clear closed loop gradually disappears and only a vaguer closed loop remains. This vague closed loop corresponds to a region expressed by green in the color image. However, the green region is brighter than the blue region and darker than the red region. Accordingly, when the inclination angle is relatively high, the brightness decreases but the viewing angle is closer to 90°. Although not shown, the pattern at the inclination angle α of 50 is similar to that at the inclination angle α of 47.5°. The pattern at the inclination angle α of 20° is similar to that at the inclination angle α of 22.5°. That is, as the inclination angle α is lower, it is possible to obtain higher brightness. As the inclination angle α is higher, it is possible to obtain a larger viewing angle. When the microlens is used in the light guiding plate, only one of the brightness and the viewing angle should not be high and the balanced brightness and viewing angle are required. Accordingly, the value of the effective inclination angle α is preferably in the range of 20° to 50°.

A method of manufacturing the microlens having a curved incline according to the invention will be described in detail now.

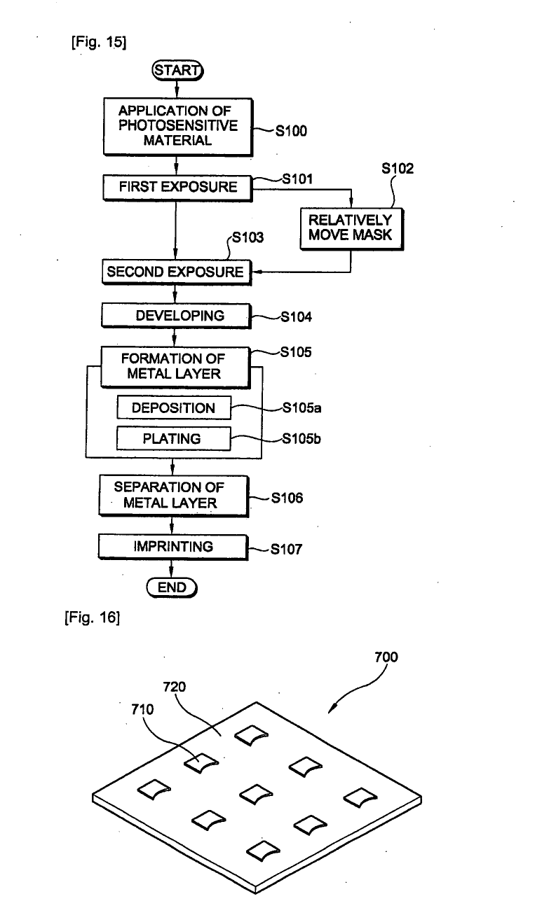

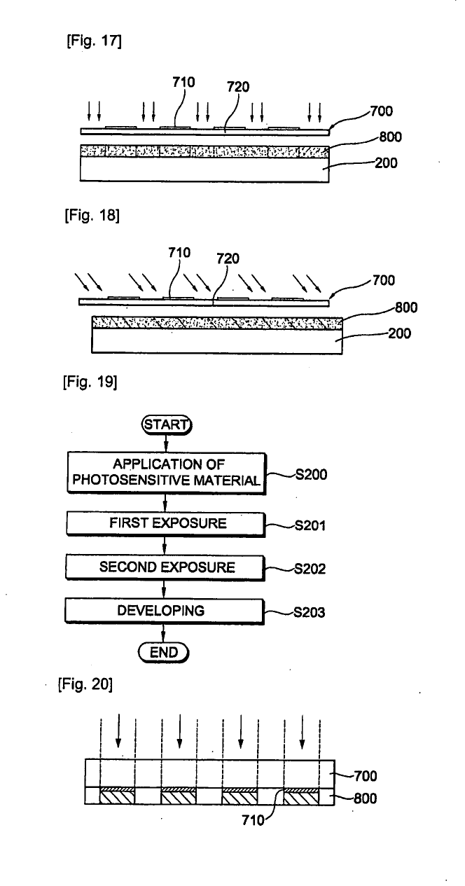

FIG. 15 is a flowchart illustrating the method of manufacturing the microlens having a curved incline formed therein according to the invention. FIG. 16 is a perspective view illustrating a mask used in the embodiment shown in FIG. 15. FIG. 17 is a diagram illustrating a first exposure step of the embodiment shown in FIG. 15. FIG. 18 is a diagram illustrating a second exposure step of the embodiment shown in FIG. 15.

In order to manufacture a microlens having a curved incline, a photosensitive material is first applied onto a surface of a substrate (photosensitive material applying step S100). The substrate can be made of a material such as silicon or glass. The photosensitive material is a material of which the physical property is changed by an ultraviolet ray or an X ray and a representative example thereof is a photoresist (PR) which is widely used in a semiconductor manufacturing process. The PR is classified into several kinds depending on reaction characteristics to light, but roughly a negative PR and a positive PR are used widely. The negative PR has a property that a portion exposed to light is not removed at the time of developing and a portion not exposed to light is removed. On the contrary, the positive PR has a property that a portion exposed to light is removed.

On the other hand, a step of softly baking the substrate on which the photosensitive material is applied may be further performed after the photosensitive material applying step S100. The baking step is preferably performed under the condition of a temperature of 70° C. to 120° C. and a time of 20 to 30 minutes.

After the photosensitive material applying step S100, light is applied thereto in a state where a mask having predetermined patterns formed thereon is placed on the substrate, thereby exposing the photosensitive material to light (first exposure step S101). Next, light is applied to the photosensitive material at an angle different from that of the first exposure step (second exposure step S103). The two exposure steps are performed to manufacture the microlens having a polyhedral shape of which at least one face is a curved face. The first exposure step S101 is to form non-curved faces and the second exposure step S103 is to form the curved face.

As shown in FIG. 16, a mask 700 is a plate-like member made of a light transmitting material and patterns 710 in which one face of a polygonal is replaced with a curve curved inward and which is made of a light blocking material are formed on one surface of the mask. Although it is shown in FIG. 16 that one face of a rectangular of the patterns 710 is replaced with a curve, one or more faces of a polygonal shape such as triangle and pentagon may be replaced with a curve. Although it is shown in FIG. 16 that the patterns 710 made of the light blocking material is formed on the base material 720 made of a light transmitting material to form the mask 700, the base material 720 may be formed of a light blocking material and then through holes may be formed in the base material, thereby using the through holes as the patterns 710.

When the photosensitive material is the positive PR and rays such as an ultraviolet ray (UV), an extreme ultraviolet ray, an e-beam, an X-ray, and an ion beam are applied to the mask 700 from the upside thereof, the rays are blocked by the patterns 710 and reach the positive PR through the portions of the mask 700 in which the patterns 710 are not formed, thereby denaturing the positive PR. Since the patterns 710 formed on the mask 700 block the light, the patterns serve as a light blocking region. Since the other portions 720 on which the patterns 710 are not formed transmits the light, the other portions serve as alight transmitting region.

The positive PR denatured by light is removed in the developing step S104. Accordingly, since only the portions of the positive PR covered with the patterns 710 remains, the same shape as the patterns 710 of the mask 700 can be formed on the substrate 200.

A film mask or a chromium mask can be used depending on the precision of the microlens. By using the chromium mask, the microlens can be manufactured with the precision of 1 μm.

The mask 700 includes the light transmitting region 720 transmitting light and the light blocking region 710 not transmitting light. The mask 700 shown in FIG. 16 employs the positive PR. When the negative PR is used as the photosensitive material, the two regions 710 and 720 can be exchanged each other. In general, the patterns to be formed on the photosensitive material is determined on the basis of the light blocking region 710 formed on the mask 700.

FIG. 17 is a diagram illustrating the first exposure step shown in FIG. 15. In the first exposure step S101, light is incident on the mask 700 so as to be substantially perpendicular to the mask. Accordingly, the photosensitive material 800 applied onto the substrate 200 is exposed into a vertical column shape having the same section as the patterns 710 of the mask 700. On the contrary, in the second exposure step S103 shown in FIG. 18, the application angle of light is tilted, unlike the first exposure step S101. Then, the photosensitive material 800 applied onto the substrate 200 is exposed into a tilted column shape having the same section as the patterns 710 of the mask 700. At this time, the tilted direction of light to be applied should correspond to the side replaced with a curve in the patterns 710 of the mask 700. For example, when the light is applied in the direction indicated by an arrow in FIG. 18, the sides replaced with a curve in the patterns 17 of the mask 700 should be located at the right end or the left end of the respective patterns 710 in the drawing.

When the exposure steps S101 and 5103 are finished, the photosensitive material 800 has a column shape in which the vertical column and the tilted column are combined, that is, a polyhedral shape of which at least one face is an incline. The incline is a curved face since it is formed by the side replaced with a curve in the patterns 710 of the mask 700. As a result, the exposed photosensitive material 800 has a polyhedral shape of which one face is a curved incline. At this time, in order to adjust the size and shape of the polyhedral shape of the photosensitive material 800, a step of horizontally moving the mask 700 relative to the substrate 200 (relative moving step S102) may be added between the first exposure step S101 and the second exposure step S102. On the other hand, although it has been described that light is applied vertical to the mask surface in the first exposure step S101 and light is applied tilted about the mask surface in the second exposure step S103, the application angle may be changed and may not be 90°.

After the second exposure step S103, the exposed photosensitive material is developed (developing step S104). The developing step S104 can be performed by the use of a dipping method of dipping the substrate in a medicine for selectively removing the exposed photosensitive material.

When the developing step S104 is finished, the substrate 200 having the microlenses 100 formed on one surface thereof is obtained. When the substrate 200 is made of a light transmitting material, the substrate can be used as a light guiding plate without any change, which is the light guiding plate according to the invention. However, a step of removing the substrate 200 may be further performed as needed to separate only the microlenses. The separated microlenses may be attached to other structures for necessary use.

On the other hand, it is not practical in view of cost and time that the photosensitive material applying step S100, the first exposure step S101, the second exposure step S103, and the developing step S104 are performed to manufacture each microlens.

Accordingly, it is preferable that the microlenses or the light guiding plate are produced in mass by the use of an imprinting method using the substrate 200 having been subjected to the developing step S104 as a stamp (imprinting step S107). Here, the microlenses or the light guiding plate to be produced has the same depressed shape as the microlenses 100 formed in the substrate 200 having been subjected to the developing step S104. That is, the stamp is a protruded stamp, since the imprinted result has the depressed shape.

However, the microlenses 100 formed by the photosensitive material are usually small in strength and thus can be easily wore or deformed in the repeated imprinting process. Accordingly, it is preferable that a metal layer forming step S105 of forming a metal layer by stacking a metal material on the substrate 200 on which the microlenses 100 are formed in the developing step S104 is further performed prior to the imprinting step S107. Then, since the strength of the substrate 200 having the microlenses 100 can be enhanced, it is possible to prevent the stamp from be worn or deformed in the imprinting step S107 which is repeatedly performed.

In addition, when the thickness of the metal layer formed on the microlenses 100 in the metal layer forming step S105 is sufficiently large, the metal layer may be separated from the substrate (metal layer separating step S106) and the separated metal layer may be used as a stamp to perform the imprinting step. In this case, it is possible to obtain microlenses having the same shape as the microlenses 100 formed on the substrate in the developing step S104 in mass. That is, this stamp is a depressed stamp, since the imprinted result has a protruded shape.

On the other hand, in the metal layer forming step S105, the metal layer can be formed by the use of a deposition method, a plating method, and a paste applying method. However, the metal layer forming step using the deposition method has a problem that much cost and time are required to sufficiently secure the thickness of the metal layer. The metal layer forming step using the plating method has a problem that an electroplating method can hardly be performed on the substrate 200 made of a non-conductive material. The metal layer forming step using the paste applying method has a problem that the precision in shape is low and thus it is not suitable for manufacturing a protruded stamp. Accordingly, the metal layer forming step S105 is preferably performed through two steps. That is, the metal layer forming step S105 can include a deposition step S105a of depositing a thin metal film on the substrate 200 having been subjected to the developing step S104 and a plating step S105b of plating the deposited thin metal film with a metal again. In this case, the metal layer separating step S106 is performed to separate the plated metal from the deposited thin metal film.

In this way, when the metal layer forming step S105 is performed through two steps of the deposition step S105a and the plating step S105b, it is possible to save the cost and the time. Even when the substrate 200 is made of a non-conductive material, the electroplating can be easily performed, thereby maintaining high precision in shape.

Although it has been described that the imprinting method using a stamp is used to produce the microlenses in mass, it is also possible to produce the microlenses by the use of an injection molding method using the substrates having been subjected to the developing step S104, the metal layer forming step S105, and the metal layer separating step S106 as a mold. By replacing the “stamp” with the “mold” and replacing the “imprinting” with the “injection molding” in the above description, it is obvious to those skilled in the art that a method of manufacturing a microlens is obtained using the injection molding method. Accordingly, the method of manufacturing a microlens using the injection molding method will be omitted.

Although it has been described that the same mask is used for the first exposure step S101 and the second exposure step S103, different masks may be used for the first exposure step S101 and the second exposure step S103, respectively. That is, in the first exposure step S101, light is applied to the substrate at a predetermined angle through a first mask having polygonal patterns of which all the sides are linear, while light is applied to the substrate at an angle different from that of the first exposure step S101 through a second mask having patterns, which have a polygonal shape of which at least one side is replaced with a curve and which have an area equal to or less than the area of the patterns of the first mask, in the second exposure step S103. That is, the patterns 710 shown in FIG. 16 are divisionally formed in two different masks and then two masks are used in two exposure steps, respectively. The curvature of the curved incline to be formed in the microlens is determined on the basis of the curvature of the curve formed in the mask patterns. Accordingly, when it is intended to manufacture microlenses having various curved inclines, it is preferable that only the second mask of which the patterns have at least one curve side is changed without changing the first mask of which the patterns have only the linear sides. Similarly, the first exposure step S101 and the second exposure step S103 may be performed sequentially with the first mask and the second mask overlapping with each other. In this case, the combination of the patterns formed in the first mask and the second mask overlapping with each other should be equal to the pattern formed in the single mask described above. That is, a single mask is divisionally formed in two masks.

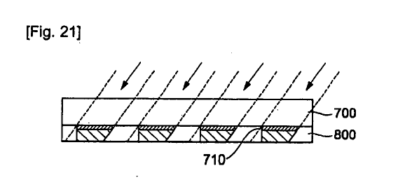

FIG. 19 is a flowchart illustrating a method of manufacturing a microlens having a curved incline formed therein according to another embodiment of the invention. FIGS. 20 and 21 are diagrams illustrating a first exposure step and a second exposure step of the embodiment shown in FIG. 19.

A method of manufacturing a microlens having a curved incline formed therein according to another embodiment of the invention includes a photosensitive material applying step S200, a first exposure step S201, a second exposure step S202, and a developing step S203.

In the photosensitive material applying step S200, a photosensitive material 800 is applied directly onto a mask 700. Here, polygonal patterns of which at least one side is replaced with a curve are formed in the mask. When the patterns are formed by punching the mask 700 to form through holes, the through holes are also covered with the photosensitive material. The photosensitive material 800 used in the photosensitive material applying step S200 and the patterns 710 formed in the mask 700 are similar to the photosensitive material used in the photosensitive material applying step S101 of the above-mentioned method of manufacturing a microlens having a curved incline and the patterns of the mask used in the first exposure step S101 and thus detailed description thereof is omitted. Details not described in the following description are similar to those described with reference to FIG. 15.

In the first exposure step (S201), light is first applied to the mask substrate 700 on which the photosensitive material 800 is formed, as shown in FIG. 20, thereby exposing the photosensitive material.

In the second exposure step S202, as shown in FIG. 21, light is secondarily applied to the mask having subjected to the first exposure step S201 at an angle different that of the first exposure step S201. For example, when light is applied to one surface of the mask 700 so as to be perpendicular to the surface of the mask in the first exposure step S201 as shown in FIG. 20, light is applied to the surface of the mask 700 so as to be tilted about the surface of the mask in the second exposure step S202 as shown in FIG. 21.

Next, the photosensitive material 800 on the mask 700 having been subjected to two exposure steps S201 and 5202 are developed in the developing step S203.

Then, the photosensitive material 800 having been subjected to the developing step S203 has the same shape as the pattern formed in the mask and serves as the microlenses.

Here, by removing the mask, independent microlenses are obtained. Without removing the panel-like mask, a light guiding plate having the microlenses is obtained. In addition, by similarly performing the steps subsequent to the metal layer forming step S105 (see FIG. 15) of the above-mentioned embodiment, it is possible to produce microlenses and light guiding plates having the microlenses in mass by the use of the imprinting method.

This embodiment is more advantageous than the previous embodiment, in that the photosensitive material is applied directly onto the mask without preparing the substrate and the mask separately, thereby simplifying the processes. Accordingly, this embodiment is more suitable for manufacturing an imprinting stamp. In the previous embodiment, the substrate and the mask should be separately prepared and the exposure step is performed in a state where both are separated from each other, a step of moving the mask relative to the substrate (relative moving step S102; see FIG. 15) should be performed between the first exposure step and the second exposure step. However, this embodiment does not require such a step.

1. A microlens having a curved incline and being made of a light transmitting material to reflect and refract light emitted from a light source, wherein the microlens has a polyhedral shape including a bottom face, a top face opposed to the bottom face, and a plurality of side faces formed between the bottom face and the top face, and
wherein at least one side face crossing a traveling direction of the light emitted from the light source among the plurality of side faces is a curved face inclined about the bottom face.

2. The microlens according to claim 1, wherein the curved face is formed so as to reduce the volume of the polyhedral shape.

3. The microlens according to claim 1, wherein the angle of the curved face inclined about the bottom face is in the range of 20° to 50°.

4. A method of manufacturing a microlens, comprising:
a photosensitive material applying step of applying a photosensitive material to a surface of a substrate;
a first exposure step of applying light to the surface of the substrate through a mask on which a polygonal pattern of which at least one side is replaced with a curve is formed;
a second exposure step of applying light to the surface of the substrate through the mask at an angle different from that of the first exposure step; and
a developing step of developing the photosensitive material exposed in the first exposure step and the second exposure step.

5. The method according to claim 4, further comprising an imprinting step of performing an imprinting operation using the developed substrate as a stamp.

6. The method according to claim 5, further comprising a metal layer forming step of forming a metal layer on the developed substrate before the imprinting step,
wherein the imprinting step is to perform an imprinting operation using the substrate having the metal layer formed thereon as a stamp.

7. The method according to claim 4, further comprising:
a metal layer forming step of forming a metal layer on the developed substrate;
a metal layer separating step of separating the metal layer from the substrate; and
an imprinting step of performing an imprinting operation using the separated metal layer as a stamp.

8. The method according to claim 7, wherein the metal layer forming step includes a deposition step of depositing a metal on the developed substrate and a plating step of plating the deposited metal with another metal, and
wherein the metal layer separating step is to separate the metal layer foitned in the plating step.

9. The method according to claim 4, further comprising a relative moving step of allowing the substrate to move relative to the mask between the first exposure step and the second exposure step.

10. The method according to claim 4, wherein the first exposure step is to apply light through a mask on which a quadrangular pattern of which one side is replaced with a curve is formed.

11. The method according to claim 10, wherein the mask is one of a film mask and a chromium mask.

12. A method of manufacturing a microlens having a curved incline formed therein, comprising:
a step of applying a photosensitive material to a surface of a substrate;
a first exposure step of applying light to the surface of the substrate through a first mask having a polygonal pattern;
a second exposure step of applying light to the surface of the substrate through a second mask having a pattern, which has a polygonal shape of which at least one side is replaced with a curve and which has an area equal to or less than that of the pattern of the first mask, at an angle different from that in the first exposure step; and
a developing step of developing the exposed photosensitive material exposed in the first exposure step and the second exposure step.

13. A method of manufacturing a microlens having a curved incline formed therein, comprising:
a photosensitive material applying step of applying a photosensitive material to a mask substrate having a polygonal pattern, at least one side of which is replaced with a curve, formed thereon;
a first exposure step of applying light to the surface of the mask substrate;
a second exposure step of applying light to the surface of the mask substrate at an angle different from that in the first exposure step; and
a developing step of developing the photosensitive material exposed in the first exposure step and the second exposure step.

14. A light guiding plate comprising:
a substrate that is made of a light transmitting material to transmit light emitted from a light source; and
a microlens that is formed to protrude from the surface of the substrate, that is made of a light transmitting material to reflect and refract the light emitted from the light source, and that has a polyhedral shape including a bottom face coming in contact with the surface of the substrate, a top face opposed to the bottom face, and a plurality of side faces formed between the bottom face and the top face,
wherein at least one side face crossing the traveling direction of the light emitted from the light source among the plurality of side faces is a curved face inclined about the bottom face.

15. The light guiding plate according to claim 14, wherein the curved face of the microlens is formed so as to reduce the volume of the microlens.

16. A light guiding plate comprising a substrate that is made of a light transmitting material to transmit light emitted from a light source and that has a micro groove of a polyhedral shape having a bottom face and a plurality of side faces,
wherein at least one face crossing the traveling direction of the light emitted from the light source among the plurality of side faces of the micro groove is a curved face inclined about the bottom face.

17. The light guiding plate according to claim 16, wherein the curved face of the micro groove is formed so as to enhance the volume of the substrate.

18. A back light unit comprising:
a light source;
a light guiding plate including a substrate that is made of a light transmitting material to transmit light emitted from a light source and a microlens that is formed to protrude from the surface of the substrate, that is made of a light transmitting material to reflect and refract the light emitted from the light source, and that has a polyhedral shape including a bottom face coming in contact with the surface of the substrate, a top face opposed to the bottom face, and a plurality of side faces formed between the bottom face and the top face, wherein at least one side face crossing the traveling direction of the light emitted from the light source among the plurality of side faces is a curved face inclined about the bottom face; and
a reflecting plate that is disposed on one surface of the light guiding plate and that reflects the light emitted from the light source.

19. A back light unit comprising:
a light source;
a light guiding plate including a substrate that is made of a light transmitting material to transmit light emitted from a light source and that has a micro groove of a polyhedral shape having a bottom face and a plurality of side faces, wherein at least one face crossing the traveling direction of the light emitted from the light source among the plurality of side faces of the micro groove is a curved face inclined about the bottom face; and
a reflecting plate that is disposed on one surface of the light guiding plate and that reflects the light emitted from the light source.

20. A display device comprising:
a light source;
a light guiding, plate including a substrate that is made of a light transmitting material to transmit light emitted from a light source and a microlens that is formed to protrude from the surface of the substrate, that is made of a light transmitting material to reflect and refract the light emitted from the light source, and that has a polyhedral shape including a bottom face coming in contact with the surface of the substrate, a top face opposed to the bottom face, and a plurality of side faces formed between the bottom face and the top face, wherein at least one side face crossing the traveling direction of the light emitted from the light source among the plurality of side faces is a curved face inclined about the bottom face;
a reflecting plate that is disposed on one surface of the light guiding plate so as to reflect the light; and
a variable mask that is disposed on the other surface of the light guiding plate and that displays an image by blocking or transmitting the light reflected and refracted by the light guiding plate.

21. A display device comprising:
a light source;
a light guiding plate including a plate-like base layer that is made of a light transmitting material to transmit light emitted from a light source and a micro groove that includes a reflecting/refracting layer formed monolithically on the base layer and made of a light transmitting material to reflect and refract the light emitted from the light source, wherein the reflecting/refracting layer is a polyhedral groove including a bottom face opposed to the surface of the base layer and a plurality of side faces and at least one side face crossing the traveling direction of the light emitted from the light source among the plurality of side faces is a curved face inclined about the bottom face;
a reflecting plate that is disposed on one surface of the light guiding plate so as to reflect light; and
a variable mask that is disposed on the other surface of the light guiding plate and that displays an image by blocking or transmitting the light reflected and refracted by the light guiding plate.

22. The display device according to claim 20, wherein the variable mask includes:
a first substrate on which electrodes assigned to pixels are arranged;
a second substrate that is bonded to the first substrate and on which an electrode common to the pixels; and
a liquid crystal layer interposed between the first substrate and the second substrate.
